(19) United States
(12) Patent Application Publication
(10) Pub. No.: US 2009/0134476 A1
(43) Pub. Date: May 28, 2009

(54) LOW TEMPERATURE COEFFICIENT FIELD EFFECT TRANSISTORS AND DESIGN AND FABRICATION METHODS

(75) Inventor: William R. Richards, JR., Cary, NC (US)

Correspondence Address: MYERS BIGEL SIBLEY & SAJOVEC, PO BOX 37428, RALEIGH, NC, 27627, US

(73) Assignee: Thunderbird Technologies, Inc.

(21) Appl. No.: 12/268,582

(22) Filed: Nov. 11, 2008

Related U.S. Application Data
(60) Provisional application No. 60/987,568, filed on Nov. 13, 2007.

(51) Int. Cl. H01L 29/78; G06F 17/50; H01L 21/336

(52) U.S. Cl. 257/403; 716/1; 438/290; 257/E29.255; 257/E21.417

(57) ABSTRACT

An accumulation mode field effect transistor includes a substrate, an insulated gate on the substrate, source and drain regions on the substrate on opposite sides of the insulated gate, a channel region that is doped a first conductivity type at a first doping concentration, and that extends into the substrate beneath the insulated gate to a channel region depth, and a counter-doped region (for example, a portion of the substrate, a tub in the substrate or a well in the substrate) beneath the channel region that is doped a second conductivity type at a second doping concentration to define a semiconductor junction therebetween at the channel region depth. The first doping concentration, the second doping concentration and the channel region depth are selected to counterbalance a threshold voltage change of the accumulation mode field effect transistor as a function of temperature against a majority carrier mobility change of the accumulation mode field effect transistor as a function of temperature, so as to provide a low temperature coefficient accumulation mode field effect transistor.

### CROSS REFERENCE TO RELATED APPLICATION

This application claims the benefit of provisional Application No. 60/987,568, filed Nov. 13, 2007, entitled Low Temperature Coefficient Field Effect Transistors and Fabrication Methods, the disclosure of which is hereby incorporated herein by reference in its entirety as if set forth fully herein.

### FIELD OF THE INVENTION

This invention relates to electronic circuits and integrated circuit devices, and more particularly to integrated circuit devices that include insulated gate field effect transistors, often referred to as Metal Oxide Semiconductor Field Effect Transistors (MOSFETs), MOS devices and/or Complementary MOS (CMOS) devices, and related design and fabrication methods.

### BACKGROUND OF THE INVENTION

Field effect transistors are widely used in integrated circuit devices, including logic, memory, processor and other integrated circuit devices. As the integration density of integrated circuit devices continues to increase, the channel length of a field effect transistor may continue to decrease into the Deep Sub Micron (DSM) range. These short channel devices may make it increasingly difficult to design high performance circuits and integrated circuits.

Conventional surface-channel MOSFETs for DSM applications are generally not designed for specific thermal characteristics. This is because a large number of factors are generally simultaneously optimized for the device to achieve predetermined performance targets. The thermal behavior of the device is simply characterized after the device design is completed and the designer is left to cope with whatever the temperature coefficients happen to be.

### SUMMARY OF THE INVENTION

An accumulation mode field effect transistor according to various embodiments of the present invention includes a substrate, an insulated gate on the substrate, source and drain regions on the substrate on opposite sides of the insulated gate, a channel region that is doped a first conductivity type at a first doping concentration, and that extends into the substrate beneath the insulated gate to a channel region depth, and a counter-doped region (for example, a portion of the substrate, a tub in the substrate or a well in the substrate) beneath the channel region that is doped a second conductivity type at a second doping concentration to define a semiconductor junction therebetween at the channel region depth. According to various embodiments, the first doping concentration, the second doping concentration and the channel region depth are selected to counterbalance a threshold voltage change of the accumulation mode field effect transistor as a function of temperature against a majority carrier mobility change of the accumulation mode field effect transistor as a function of temperature, so as to provide a low temperature coefficient accumulation mode field effect transistor.

In other embodiments, the first doping concentration, the second doping concentration and the channel region depth are selected to establish a temperature-independent point where, for a given gate voltage that is applied to the insulated gate, the threshold voltage change of the accumulation mode field effect transistor as a function of temperature is about equal to the majority carrier mobility change of the accumulation mode field effect transistor as a function of temperature. In other embodiments, the temperature-independent point is selected such that the given gate voltage is about equal to the threshold voltage of the accumulation mode field effect transistor. In other embodiments, the temperature-independent point is selected such that the given gate voltage is close to the supply voltage of the accumulation mode field effect transistor. In still other embodiments, the first doping concentration, the second doping concentration, the channel region depth and a work function of the insulated gate are selected as described above.

Embodiments of the invention have been described above in connection with accumulation mode field effect transistors. However, analogous methods of designing accumulation mode field effect transistors and of fabricating accumulation mode field effect transistors, may be provided according to other embodiments.

### BRIEF DESCRIPTION OF THE DRAWINGS

FIG. 1 is a cross-section of a channel of a accumulation mode field effect transistor and a graph of doping versus depth according to various embodiments.

FIG. 2 is a cross-section of an n-channel accumulation mode field effect transistor according to various embodiments.

FIG. 3 graphically illustrates saturation current with gate and drain voltages equal to the supply voltage versus temperature for an example of a short channel inversion (SCI) and an accumulation mode MOSFET according to various embodiments.

FIG. 4 graphically illustrates drain current versus gate voltage as a function of temperature according to various embodiments.

FIG. 5 graphically illustrates surface channel inversion field effect transistor threshold voltage versus temperature as a function of channel doping according to various embodiments.

FIG. 6 graphically illustrates a buried channel accumulation MOSFET threshold voltage versus temperature for various values of channel doping according to various embodiments.

FIG. 7 graphically illustrates measured threshold voltage versus temperature for an accumulation mode PMOSFET according to various embodiments.

FIG. 8 graphically illustrates drain current versus gate voltage as a function of temperature for an accumulation PMOSFET according to various embodiments.

### DETAILED DESCRIPTION

It has been discovered that accumulation mode field effect transistors may be designed and built with extremely low temperature coefficients in drive current, with gate voltage and drain voltage equal to the supply voltage. A reason for this unpredictable result is that counter-doped devices belong to a class of MOSFETs which may be considered accumulation, rather than inversion devices. These devices use a counter-doped channel, similar to the buried-channel devices in common use many years ago. These transistors may be Fermi-FET transistors, and/or other devices that belong to a class of MOSFETs which may be termed accumulation, rather than inversion devices. These devices use a counter-doped channel. Fermi-FET transistors are described, for example, in U.S. Pat. Nos. 4,984,043; 4,990,974; 5,151,759; 5,194,923; 5,222,039; 5,367,186; 5,369,295; 5,371,396; 5,374,836; 5,438,007; 5,440,160; 5,525,822; 5,543,654; 5,698,884; 5,786,620; 5,814,869; 5,885,876; and 6,555,872, and U.S. Patent Application Publication Nos. US 2006/0138548 and US 2007/0001199, assigned to the assignee of the present invention, the disclosures of all of which are incorporated herein by reference in their entirety as if set forth fully herein.

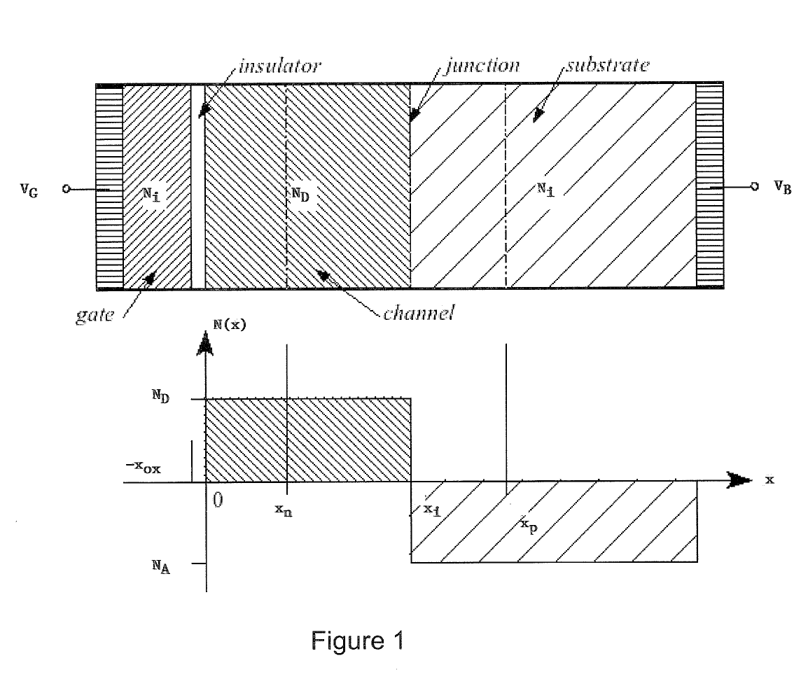

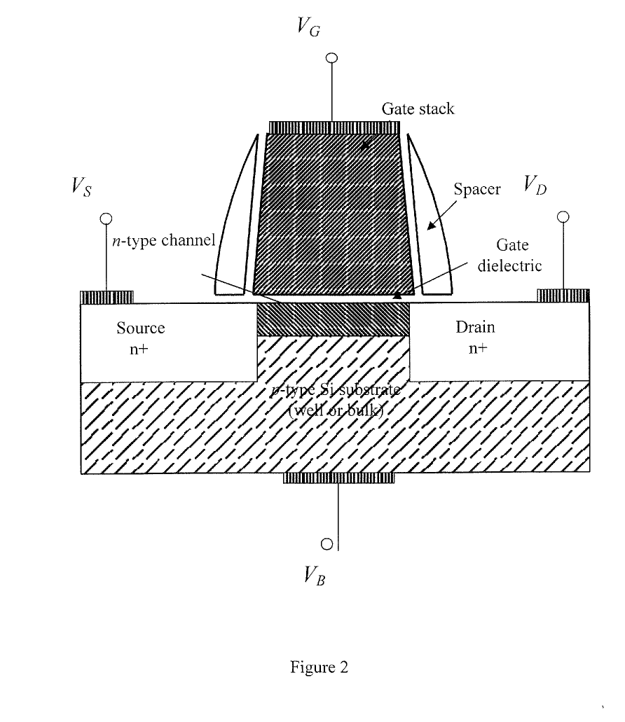

FIG. 1 illustrates a 1-D counter-doped MOSFET channel. This is similar to the buried-channel architecture widely used in the days of single-work function poly-gate CMOS technologies. Since the dopant type is n-type at the surface, where the channel ultimately forms, with n-type source/drains as in FIG. 2, this device may be considered an accumulation rather than an inversion n-type enhancement mode MOSFET. The same considerations may be applied to a p-channel enhancement mode structure: the polarities of the dopants in the silicon would be reversed (n for p, and vice-versa) and the gate stack may change to provide the desired threshold voltage. In FIGS. 1 and 2, the insulated gate includes a gate dielectric or insulator and a single or multiple layer conductive gate, also referred to as a gate stack.

Note the presence of the channel semiconductor junction in FIGS. 1 and 2, which does not exist in surface-channel inversion (SCI) MOSFETs. Rather than a simple surface doping to set the threshold voltage (a single parameter) as in the SCI MOSFET, it can be seen that three parameters can be simultaneously considered to set the threshold for a counter-doped or accumulation MOSFET: the channel doping concentration N_{D}, the counter-doped region doping concentration (from the substrate, tub or well adjacent the channel) N_{A} and the channel region depth xᵢ. There is not a unique solution to the threshold voltage when all three of these parameters are free to be adjusted.

$${V}_{T} = {V}_{FB} + 2 {ϕ}_{F} + \frac{\sqrt{( 2 q {ɛ}_{s} {N}_{A} ( 2 {ϕ}_{F} ) )}}{{C}_{ox}} \qquad 1 )$$

Equation 1 is the well known expression for an SCI MOSFET threshold voltage. This expression for threshold is a strong function of the doping N_{A}, and the flat-band voltage V_{FB}. For the accumulation MOSFET, the threshold definition is quite a bit more complex. Since two doping concentrations and a junction depth are to be considered, there are two cases to consider. The first case is where the junction is shallow, so that xₙ<0, referring to FIG. 1. In this case, the MOSFET channel forms at the surface and remains at the surface through all the regions of operation. This may be termed a Surface Channel Accumulation (SCA) device. For this case the threshold voltage may be expressed as defined in B. L. Austin, “Performance Analysis and Scaling Opportunities of Bulk CMOS Inversion and Accumulation Devices,” Ph.D. dissertation, Georgia Tech, Atlanta, Ga., May 2001, the disclosure of which is hereby incorporated herein by reference in its entirety as if set forth fully herein:

$${V}_{T} = {V}_{FB} + {V}_{bi} + \frac{{qN}_{A}}{{C}_{ox}} \sqrt{{X}_{{i}^{2}} ( 1 + \frac{{N}_{D}}{{N}_{A}} ) + \frac{2 {ɛ}_{Si} {V}_{bi}}{{qN}_{A}}} - \frac{q}{{C}_{ox}} ( {N}_{A} + {N}_{D} ) {X}_{i} \qquad 2 )$$

The other case is where xₙ>0, which is the buried-channel device, where the channel forms sub-surface (at x=xₙ) at threshold, followed by surface conduction as V_{GS} is increased beyond V_{T}. This may be termed a Buried Channel Accumulation (BCA) device. In this case, the threshold voltage may be expressed as defined in B. L. Austin dissertation incorporated above:

$${V}_{T} = {V}_{FB} + \frac{{N}_{D}}{{N}_{D} + {N}_{A}} {V}_{bi} + ( \frac{1}{{C}_{i}} + \frac{1}{{C}_{ox}} ) \sqrt{\frac{2 q {ɛ}_{s} {N}_{A} {N}_{D}}{( {N}_{A} + {N}_{D} )} {V}_{bi}} - {qN}_{D} {X}_{i} ( \frac{1}{2 {C}_{i}} + \frac{1}{{C}_{ox}} ) \qquad 3 )$$

It can be seen in both 2) and 3) that a number of combinations of values for N_{D}, N_{A} and xᵢ may be used to arrive at a specific V_{T} value. This allows for freedom in designing for other criteria, such as thermal behavior.

FIG. 2 illustrates a cross-sectional representation of a counter-doped, or accumulation MOSFET structure, defining the terminals and terminal biases. The well-known first-order expression for MOSFET saturation current is:

$${I}_{DSAT} = \frac{1}{2} μ {C}_{ox} \frac{W}{L} {( {V}_{GS} - {V}_{T} )}^{2} \qquad 4 )$$

The two terms with significant temperature dependence are the majority carrier mobility μ and the threshold voltage V_{T}. The threshold voltage decreases as a function of temperature in a nearly linear fashion, causing the drain current to rise. Typical values of the threshold temperature coefficient are −1 to −5 mV per degree C. Counter to this however, is the majority carrier mobility temperature dependence, which also decreases, but non-linearly with increasing temperature. Since the current is directly proportional to the mobility as in 4), this becomes a stronger effect on the current than the threshold voltage as V_{GS} is increased far above V_{T}. So the threshold decrease tends to increase drain current while the mobility decrease tends to decrease it. It can be seen that it should be possible to counterbalance and even cancel these two trends at a specific bias point, as a function of MOSFET design parameters. Indeed it is possible, but for practical MOSFET device designs, the conventional SCI MOSFET design may not allow enough degrees of freedom to allow the temperature compensation to be adjusted as desired. SCI MOSFET devices have been studied recently regarding a temperature-independent point and it has been shown that this temperature-independent point is commonly observed, but at gate voltages much nearer the threshold voltage than the supply voltage as shown in Leung Wing Yan, et. al., “Effect of technology scaling on temperature independent point (TIP) in MOS transistors”, IEEE 2006 8th International Conference on Solid-State and Integrated Circuit Technology, 23-26 Oct. 2006, the disclosure of which is hereby incorporated herein by reference in its entirety as if set forth fully herein.

The mobility and its temperature dependence are both a strong function of the doping concentrations as well as the channel architecture. The previous work appears to have only recognized the dependence upon the SCI MOSFET channel doping concentration. Due to the increased degrees of freedom available for accumulation device design, the doping profiles may be configured so that the threshold, mobility and resulting thermal behavior all meet specific thermal criteria, for example a temperature-independent point much nearer the supply voltage

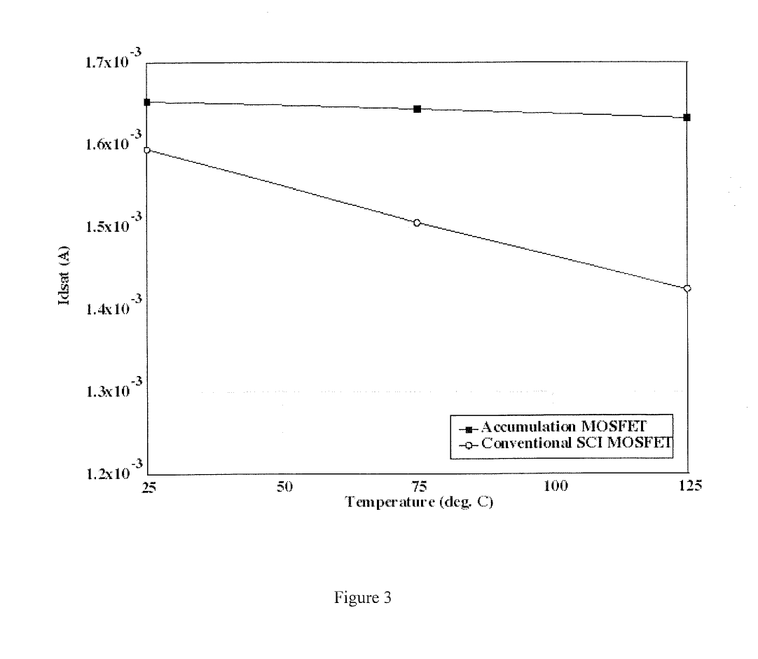

Accumulation devices have been designed, fabricated and measured for low drain current temperature coefficients, as shown in FIG. 3. It can be seen that the accumulation saturation current exhibits significantly reduced temperature dependence, compared with the conventional SCI MOSFET behavior. The saturation current was not measured at a specific gate voltage corresponding to the TIP, as in previous studies, but is the true saturation current, defined as the gate voltage and drain voltage being equal to the supply voltage. These devices were fabricated within the same experimental lot, differing only in the gate stack and channel implants.

In order to explore this analytically, consider the temperature behavior of the two dominant terms in the I_{DSAT} expression 4) above. The temperature behaviors of both the mobility and threshold voltage for silicon MOSFETs have been known for a number of years, as studied in I. M. Filanovsky, et. al., “Mutual compensation of mobility and threshold voltage temperature effects with applications in CMOS circuits”, IEEE Transactions on Circuits and Systems-I: Fundamental Theory and Application, Vol. 48, No. 7, July, 2001, the disclosure of which is hereby incorporated herein by reference in its entirety as if set forth fully herein. Empirical relations suitable for simple circuit-level modeling may be defined as stated in Yannis P. Tsividis, Operation and Modeling of the MOS Transistor, McGraw-Hill, NY, 1987, the disclosure of which is hereby incorporated herein by reference in its entirety as if set forth fully herein, as follows:

$$\begin{matrix}{V}_{T} ( T ) = {V}_{T 0} - {k}_{1} ( T - {T}_{0} ) \\ and & 5 ) \\ μ ( T ) = \frac{{μ}_{0}}{1 + Θ ( {V}_{GS} - {V}_{T} )} {( \frac{T}{{T}_{0}} )}^{- {k}_{2}} & 6 )\end{matrix}$$

The parameters Θ, k₁ and k₂ are fitting parameters which are typically extracted from device measurements and are functions of the technology parameters such as oxide thickness and channel doping profiles. To is the reference temperature, e.g. 300 K. Equation 4) may be rewritten using these expressions as follows:

I_{DSAT}(T)=βμ(T)(V_{GS}−V_{T}(T))² 7)

where

$$β = \frac{1}{2} \frac{W}{L} {C}_{ox} .$$

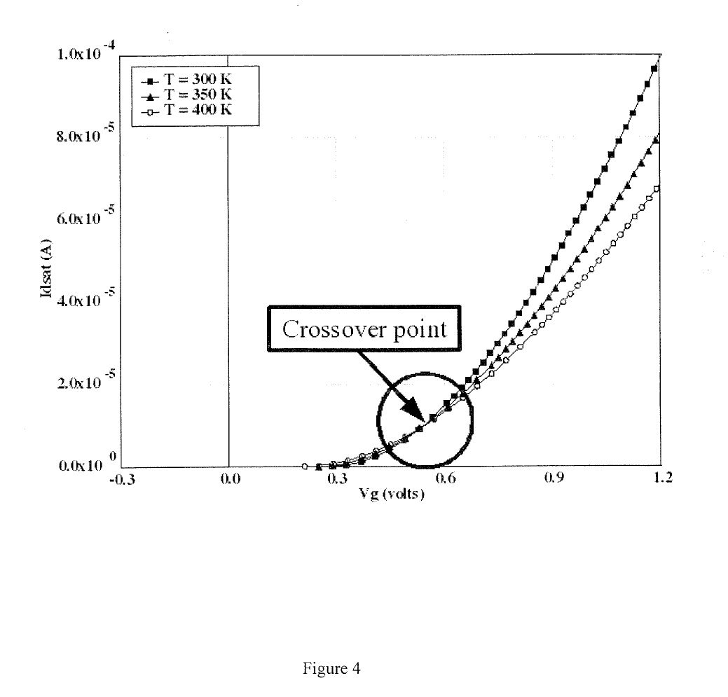

FIG. 4 illustrates 7) at several different temperatures for an SCI device architecture. The doping for the device of FIG. 4 is N_{A}=3×10¹⁷ with T_{OX}=5 nm. Note the crossover point in I_{DS}. Thus, there is a V_{GS} value where the current is nearly independent of temperature. The V_{T} at T=300 K is 0.285 V, thus this particular crossover occurs at V_{T}+0.265 V. This behavior is observed for simulated MOSFETs, as well as physically measured devices and appears to be universal. The same general behavior exists for SCA, BCA and SCI devices. The channel architecture seems to make no difference; in every case explored, there was a crossover or temperature-independent point in the I_{D}-V_{G} curves which is the point where the V_{T} trend and the mobility trend cancel.

For a very low I_{DSAT} temperature coefficient it would be desirable to design a MOSFET device which would establish this crossover point close to the supply voltage V_{DD}. With a conventional SCI MOSFET, this may not be practical. The crossover or temperature-independent point for an SCI MOSFET is generally limited to 200-300 mV above V_{T} due to the constraints on the surface channel doping for an enhancement mode MOSFET with a band-edge gate material. With an accumulation MOSFET, a much wider range of doping conditions is possible, allowing different gate work functions to be used, and allowing the crossover or temperature-independent point to be shifted closer to V_{DD}.

One approach for doing this is to use varying doping conditions for both N_{A} and N_{D}, along with the junction depth xᵢ, and the gate work function to set the V_{T} where desired, while simultaneously modifying the temperature behavior as desired. To consider how this may be done, expand 6) for the temperature dependence more explicitly, so that I_{DS} is as follows:

$${I}_{DS} ( T ) = β \frac{{μ}_{0}}{1 + Θ ( {V}_{GS} - {V}_{T0} + {k}_{1} ( T - {T}_{0} ) )} {( \frac{- T}{{T}_{0}} )}^{- {k}_{2}} {( {V}_{GS} - {V}_{0} + {k}_{1} ( T - {T}_{0} ) )}^{2} \qquad 8 )$$

The parameter k₁, which is the slope of the V_{T}-T curve, is a strong function of doping and the channel architecture. It is not immediately predictable, however, from this expression how the magnitudes of the k₁ and k₂ parameters influence the overall temperature dependence of I_{DSAT}. Note that k₁ influences the both mobility of the device as well as the overdrive term in the I_{DSAT} expression. The k₁ parameter is most easily modified by the channel architecture.

Two-dimensional simulations may be used to explore the relationships more effectively, since the fundamental physics responsible for temperature effects in semiconductors is well-known. Consider a two-dimensional simulation of SCI and BCA MOSFET long channel-length structures, with channel doping concentrations identical in magnitude and the same T_{OX}. It would be expected that bulk mobility would be similar for these two devices, since the total doping levels in the channel are the same.

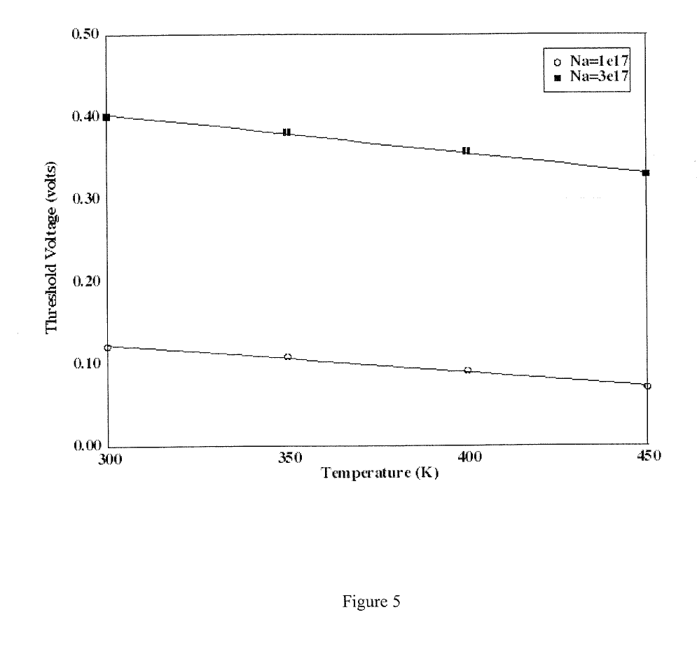

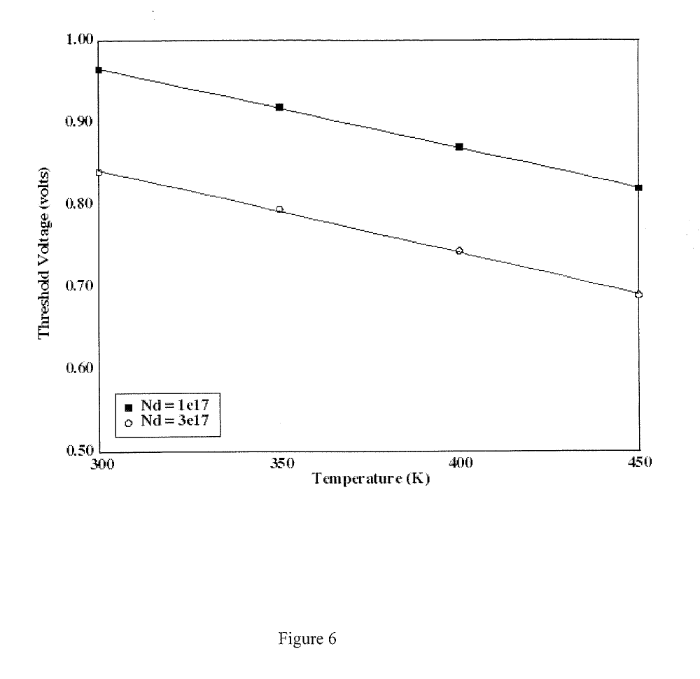

FIG. 5 shows the V_{T} of an SCI MOSFET with temperature for two different channel dopings. The gate is n+ poly. However, other materials could be used. It can be seen that the two slopes (for N_{A}=10¹⁷ cm⁻³ and N_{A}=3×10¹⁷ cm⁻³) are very nearly the same. FIG. 6 shows the V_{T} of a BCA MOSFET vs. temperature with the same channel doping magnitudes. The gate type for this device is p+ poly. However, other materials could be used. It can be clearly seen that the V_{T} rolloff for the BCA MOSFET is much stronger with temperature for both doping levels (N_{D}=10¹⁷ cm⁻³ and N_{D}=3×10¹⁷ cm⁻³), meaning a higher k₁ parameter value. Note that this is likely due to the fact that the band-bending or surface potential-V_{GS} relationship is different between the BCA and SCI MOSFETs: the physical formation of the conduction channel happens differently. Examining 8), it can be seen that this would have the effect of extending the V_{GS} crossover point in FIG. 4, since the more rapid V_{T} decrease will over-compensate the mobility degradation. Table 1 shows the k₁ parameters as a function of the doping concentrations and channel type.

TABLE 1
V_{T} variations with temperature with
channel doping concentrations.

| | Total Doping = | Total Doping = |
|---|---|---|
| Device Type | 1 × 10¹⁷ cm⁻³ | 3 × 10¹⁷ cm⁻³ |
| SCI MOSFET | −0.00034 V/° K | −0.00048 V/° K |
| BCA MOSFET | −0.00097 V/° K | −0.00010 V/° K |

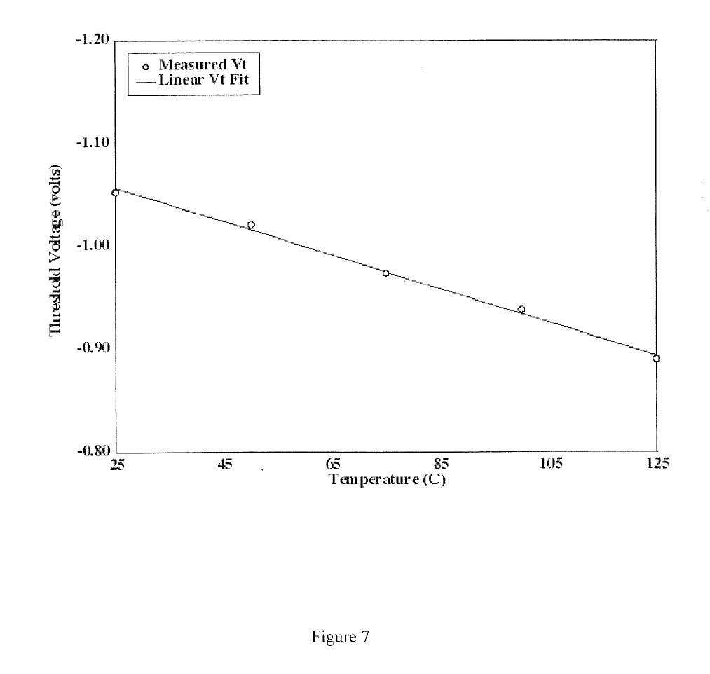

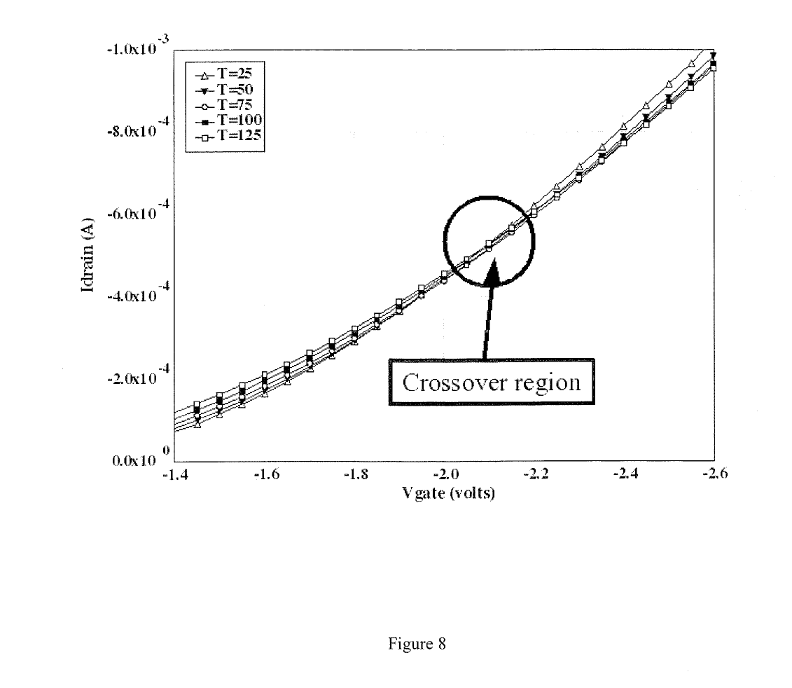

This effect has been observed experimentally as well as in fabricated devices, as shown in FIGS. 7 and 8. FIG. 7 shows the V_{T} rolloff measured for a p-channel counter-doped MOSFET, while FIG. 8 shows the crossover or temperature-independent point in an Id-Vg plot for the same device. The measured k₁ parameter for this particular device was −0.00164. It can be seen that the crossover or temperature-independent point is above 2.0 V in this case. The threshold voltage in this case was near 0.8 V, illustrating that the temperature-independent point may be moved substantially closer to the supply voltage by using an accumulation channel architecture, according to various embodiments.

Accordingly, it is possible to optimize counter-doped channel (accumulation) MOSFETs to achieve very low temperature coefficients in I_{DSAT}. The low temperature coefficients may be achieved by balancing between the threshold voltage, V_{T}, decrease with temperature, and the mobility decrease with temperature. With accumulation MOSFETs, the slope of the V_{T} rolloff with temperature is stronger and more controllable, while the surface field is lower, leading to different mobility behavior. Since the accumulation MOSFET provides more design degrees of freedom, including three channel dopant-related parameters as well as gate work function, it is possible to design devices with I_{DSAT} temperature coefficients significantly reduced compared to comparable convention surface-channel inversion MOSFETs.

The present invention has been described herein with reference to the accompanying drawings, in which exemplary embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Moreover, each embodiment described and illustrated herein includes its complementary conductivity type embodiment as well. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items and may be abbreviated as “/”.

Embodiments of the invention are described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. An accumulation mode field effect transistor comprising:
a substrate;
an insulated gate on the substrate;
source and drain regions in the substrate on opposite sides of the insulated gate;
a channel region that is doped a first conductivity type at a first doping concentration and that extends into the substrate beneath the insulated gate to a channel region depth; and
a counter-doped region beneath the channel region that is doped a second conductivity type at a second doping concentration to define a semiconductor junction therebetween at the channel region depth,
wherein the first doping concentration, the second doping concentration and the channel region depth are selected to counterbalance a threshold voltage change of the accumulation mode field effect transistor as a function of temperature against a carrier mobility change of the accumulation mode field effect transistor as a function of temperature so as to provide a low temperature coefficient accumulation mode field effect transistor.

2. An accumulation mode field effect transistor according to claim 1 wherein the first doping concentration, the second doping concentration and the channel region depth are selected to establish a temperature-independent point where, for a given gate voltage that is applied to the insulated gate, the threshold voltage change of the accumulation mode field effect transistor as a function of temperature is about equal to the majority carrier mobility change of the accumulation mode field effect transistor as a function of temperature.

3. An accumulation mode field effect transistor according to claim 2 wherein the temperature-independent point is selected such that the given gate voltage is about equal to the threshold voltage of the accumulation mode field effect transistor.

4. An accumulation mode field effect transistor according to claim 2 wherein the temperature-independent point is selected such that the given gate voltage is close to a supply voltage of the accumulation mode field effect transistor.

5. An accumulation mode field effect transistor according to claim 1 wherein the first doping concentration, the second doping concentration, the channel region depth and a work function of the insulated gate are selected to counterbalance a threshold voltage change of the accumulation mode field effect transistor as a function of temperature against a majority carrier mobility change of the accumulation mode field effect transistor as a function of temperature so as to provide the low temperature coefficient accumulation mode field effect transistor.

6. An accumulation mode field effect transistor according to claim 1 wherein the counter-doped region comprises a portion of the substrate, a tub in the substrate or a well in the substrate adjacent the channel region.

7. A method of designing an accumulation mode field effect transistor that includes a substrate, an insulated gate on the substrate, source and drain regions in the substrate on opposite sides of the insulated gate, a channel region that is doped a first conductivity type at a first doping concentration and that extends into the substrate beneath the insulated gate to a channel region depth and a counter-doped region beneath the channel region that is doped a second conductivity type at a second doping concentration to define a semiconductor junction therebetween at the channel region depth, the method of designing an accumulation mode field effect transistor comprising:
selecting the first doping concentration, the second doping concentration and the channel region depth to counterbalance a threshold voltage change of the accumulation mode field effect transistor as a function of temperature against a majority carrier mobility change of the accumulation mode field effect transistor as a function of temperature so as to provide a low temperature coefficient accumulation mode field effect transistor.

8. A method of designing an accumulation mode field effect transistor according to claim 7 wherein selecting the first doping concentration, the second doping concentration and the channel region depth to counterbalance comprises selecting the first doping concentration, the second doping concentration and the channel region depth to establish a temperature-independent point where, for a given gate voltage that is applied to the insulated gate, the threshold voltage change of the accumulation mode field effect transistor as a function of temperature is about equal to the majority carrier mobility change of the accumulation mode field effect transistor as a function of temperature.

9. A method of designing an accumulation mode field effect transistor according to claim 8 wherein selecting the first doping concentration, the second doping concentration and the channel region depth to establish a temperature-independent point comprises selecting the temperature-independent point such that the given gate voltage is about equal to the threshold voltage of the accumulation mode field effect transistor.

10. A method of designing an accumulation mode field effect transistor according to claim 8 wherein selecting the first doping concentration, the second doping concentration and the channel region depth to establish a temperature-independent point comprises selecting the temperature-independent point such that the given gate voltage is close to a supply voltage of the accumulation mode field effect transistor.

11. A method of designing an accumulation mode field effect transistor according to claim 7 wherein selecting the first doping concentration, the second doping concentration and the channel region depth to counterbalance comprises selecting the first doping concentration, the second doping concentration, the channel region depth and a work function of the insulated gate to counterbalance a threshold voltage change of the accumulation mode field effect transistor as a function of temperature against a majority carrier mobility change of the accumulation mode field effect transistor as a function of temperature so as to provide the low temperature coefficient accumulation mode field effect transistor.

12. A method of designing an accumulation mode field effect transistor according to claim 7 wherein the counter-doped region comprises a portion of the substrate, a tub in the substrate or a well in the substrate adjacent the channel region.

13. A method of fabricating an accumulation mode field effect transistor that includes a substrate, an insulated gate on the substrate, source and drain regions in the substrate on opposite sides of the insulated gate, a channel region that is doped a first conductivity type at a first doping concentration and that extends into the substrate beneath the insulated gate to a channel region depth and a counter-doped region beneath the channel region that is doped a second conductivity type at a second doping concentration to define a semiconductor junction therebetween at the channel region depth, the method of fabricating an accumulation mode field effect transistor comprising:
fabricating the first doping concentration, the second doping concentration and the channel region depth to counterbalance a threshold voltage change of the accumulation mode field effect transistor as a function of temperature against a majority carrier mobility change of the accumulation mode field effect transistor as a function of temperature so as to provide a low temperature coefficient accumulation mode field effect transistor.

14. A method of fabricating an accumulation mode field effect transistor according to claim 13 wherein fabricating the first doping concentration, the second doping concentration and the channel region depth to counterbalance comprises fabricating the first doping concentration, the second doping concentration and the channel region depth to establish a temperature-independent point where, for a given gate voltage that is applied to the insulated gate, the threshold voltage change of the accumulation mode field effect transistor as a function of temperature is about equal to the majority carrier mobility change of the accumulation mode field effect transistor as a function of temperature.

15. A method of fabricating an accumulation mode field effect transistor according to claim 14 wherein fabricating the first doping concentration, the second doping concentration and the channel region depth to establish a temperature-independent point comprises fabricating the temperature-independent point such that the given gate voltage is about equal to the threshold voltage of the accumulation mode field effect transistor.

16. A method of fabricating an accumulation mode field effect transistor according to claim 14 wherein fabricating the first doping concentration, the second doping concentration and the channel region depth to establish a temperature-independent point comprises fabricating the temperature-independent point such that the given gate voltage is close to a supply voltage of the accumulation mode field effect transistor.

17. A method of fabricating an accumulation mode field effect transistor according to claim 13 wherein fabricating the first doping concentration, the second doping concentration and the channel region depth to counterbalance comprises fabricating the first doping concentration, the second doping concentration, the channel region depth and a work function of the insulated gate to counterbalance a threshold voltage change of the accumulation mode field effect transistor as a function of temperature against a majority carrier mobility change of the accumulation mode field effect transistor as a function of temperature so as to provide the low temperature coefficient accumulation mode field effect transistor.

18. A method of fabricating an accumulation mode field effect transistor according to claim 13 wherein the counter-doped region comprises a portion of the substrate, a tub in the substrate or a well in the substrate adjacent the channel region.
